(19) United States
(12) Patent Application Publication
(10) Pub. No.: US 2007/0054424 A1
(43) Pub. Date: Mar. 8, 2007

(54) Semiconductor heating heater holder and semiconductor manufacturing apparatus

(76) Inventors: Masuhiro Natsuhara, Itami-shi (JP); Akira Mikumo, Itami-shi (JP); Tomoyuki Awazu, Itami-shi (JP); Hirohiko Nakata, Itami-shi (JP)

Correspondence Address: MCDERMOTT WILL & EMERY LLP, 600 13TH STREET, N.W., WASHINGTON, DC, 20005-3096, US

(21) Appl. No.: 11/504,764

(22) Filed: Aug. 16, 2006

(30) Foreign Application Priority Data
Aug. 19, 2005 (JP) JP 2005-238227
Aug. 19, 2005 (JP) JP 2005-238242
Sep. 12, 2005 (JP) JP 2005-263184

(51) Int. Cl. H01L 21/66

(52) U.S. Cl. 438/15

(57) ABSTRACT

A semiconductor heater holder for setting a heater for heating a semiconductor, having an opening, wherein the heat capacity of the semiconductor heater holder is not more than 1.5 times the heat capacity of the heater, and a semiconductor manufacturing apparatus comprising this semiconductor heater holder.

### BACKGROUND OF THE INVENTION

1. Field of the Invention

The present invention relates to a semiconductor heater holder and a semiconductor manufacturing apparatus, and more particularly, it relates to a semiconductor heater holder for setting a heater suitably applied to a semiconductor manufacturing apparatus such as a coater/developer employed in a photolithographic step and a semiconductor manufacturing apparatus comprising the same.

2. Description of the Background Art

In general, various treatments such as film formation and etching are performed on a semiconductor wafer to be treated in semiconductor manufacturing steps. A semiconductor manufacturing apparatus employed for such treatments of the semiconductor wafer employs a heater for holding and heating the semiconductor wafer.

In a photolithographic step, for example, the following treatment is performed: First, the semiconductor wafer is washed and thereafter dried by heating. Then the semiconductor wafer is cooled, and the surface of the cooled semiconductor wafer is coated with resist. Then, the semiconductor wafer is set on a heater set in a semiconductor heater holder provided in a photolithographic apparatus, so that the heater heats the semiconductor wafer for drying the resist. Thereafter the resist on the semiconductor wafer is exposed and developed.

### SUMMARY OF THE INVENTION

In this photolithographic step, the temperature for drying the resist remarkably influences the quality of the dried resist. Therefore, temperature uniformity of the semiconductor wafer and the heater is important in heating of the semiconductor wafer.

In order to improve the throughput, it is also desired to reduce the time for uniformizing the temperature of the semiconductor wafer.

Accordingly, an object of the present invention is to provide a semiconductor heater holder capable of improving temperature uniformity of a semiconductor wafer or a heater when heating the semiconductor wafer and a semiconductor manufacturing apparatus comprising the same.

Another object of the present invention is to provide a semiconductor heater holder capable of reducing the time for uniformizing the temperature of a semiconductor wafer when heating the semiconductor wafer and a semiconductor manufacturing apparatus comprising the same.

According to a first aspect of the present invention, a semiconductor heater holder for setting a heater for heating a semiconductor, having an opening, wherein the heat capacity of the semiconductor heater holder is not more than 1.5 times the heat capacity of the heater can be provided.

According to the first aspect of the present invention, the heat capacity of the semiconductor heater holder is preferably not more than the heat capacity of the heater.

According to the first aspect of the present invention, the heat capacity of the semiconductor heater holder is preferably at least 0.2 times the heat capacity of the heater.

According to a second aspect of the present invention, a semiconductor heater holder for setting a heater for heating a semiconductor, having an opening wherein the surface roughness Ra of the semiconductor heater holder is not more than 10 μm can be provided.

According to the second aspect of the present invention, the surface roughness Ra of the semiconductor heater holder is preferably not more than 5 μm.

According to a third aspect of the present invention, a semiconductor heater holder for setting a heater for heating a semiconductor, having an opening, a bottom portion opposed to the opening and a side portion extending from the periphery of the bottom portion toward the opening, wherein at least one of the bottom portion and the side portion is provided with a through-hole and the area of the through-hole is not more than the area of a circle having a diameter corresponding to the height of the semiconductor heater holder can be provided.

According to the third aspect of the present invention, the semiconductor heater holder is preferably provided with a plurality of through-holes to satisfy the relation A×B≧1 assuming that A (mm) represents the minimum distance between the through-holes and B (mm) represents the thickness of the holder.

The semiconductor heater holder according to the third aspect of the present invention preferably has a support member forming a space between the semiconductor heater holder and a support when the semiconductor heater holder is set on the support.

In the semiconductor heater holder according to each of the first to third aspects of the present invention, the heater is preferably a ceramics heater prepared from ceramics mainly composed of aluminum nitride, silicon nitride, silicon carbide, aluminum oxide or aluminum oxynitride.

In the semiconductor heater holder according to each of the first to third aspects of the present invention, the heater is preferably a ceramics heater prepared from ceramics mainly composed of aluminum nitride.

The semiconductor heater holder according to each of the first to third aspects of the present invention is preferably made of metal.

The semiconductor heater holder according to each of the first to third aspects of the present invention may have a cooling unit. A fluid is preferably introduced into the cooling unit.

The present invention also provides a semiconductor manufacturing apparatus comprising the aforementioned semiconductor heater holder.

According to the present invention, a semiconductor heater holder capable of improving temperature uniformity of a semiconductor wafer or a heater when heating the semiconductor wafer and a semiconductor manufacturing apparatus comprising the same can be provided.

The present invention provides a semiconductor heater holder capable of reducing the time for uniformizing the temperature of a semiconductor wafer when heating the semiconductor wafer and a semiconductor manufacturing apparatus comprising the same.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of an exemplary semiconductor heater holder according to the present invention on which a heater is set;

FIG. 2 is a schematic sectional view of another exemplary semiconductor heater holder according to the present invention on which a heater is set;

FIG. 3 is a schematic sectional view of still another exemplary semiconductor heater holder according to the present invention on which a heater is set;

FIG. 4 is a schematic sectional view of a further exemplary semiconductor heater holder according to the present invention on which a heater is set;

FIG. 5 is a schematic sectional view of a further exemplary semiconductor heater holder according to the present invention on which a heater is set;

FIG. 6 is a schematic sectional view of a further exemplary semiconductor heater holder according to the present invention on which a heater is set;

FIG. 7 is a schematic sectional view showing an exemplary state of setting the inventive semiconductor heater holder on a support;

FIG. 8 is a schematic sectional view showing another exemplary state of setting the inventive semiconductor heater holder on a support; and

FIG. 9 is a schematic sectional view showing still another exemplary state of setting the inventive semiconductor heater holder on a support.

### DESCRIPTION OF THE PREFERRED EMBODIMENTS

Embodiments of the present invention are now described. In the drawings of the present invention, it is assumed that the same reference numerals denote identical or corresponding portions.

### First Embodiment

In a semiconductor heater holder (hereinafter simply referred to as “holder”) employed in a semiconductor manufacturing apparatus such as a coater/developer, a heater is generally set on an opening provided on an upper portion of the holder to expose a wafer receiving surface of the heater for receiving a semiconductor wafer. In this holder, it follows that heat generated from the heater when heating the semiconductor wafer is transmitted to the holder through conduction, convection and radiation.

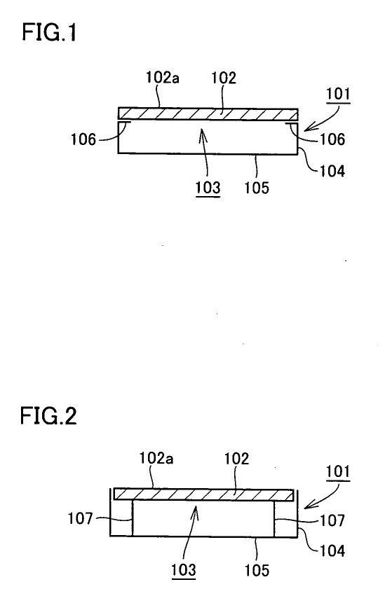

FIG. 1 is a schematic sectional view of an exemplary holder according to the present invention on which a heater is set. The inventive holder 101 is constituted of a bottom portion 105, an opening 103 opposed to bottom portion 105 at a prescribed interval, a side portion 104 extending from the periphery of bottom portion 105 toward opening 103 and a horizontal support portion 106 extending from an end of side portion 104 toward opening 103 in parallel with bottom portion 105.

A heater 102 is set on opening 103 of holder 101 to be supported by horizontal support portion 106, thereby constituting a semiconductor heating apparatus. A semiconductor wafer is set on a wafer receiving surface 102a of heater 102 of this semiconductor heating apparatus, and it follows that heater 102 heats the semiconductor wafer.

In the semiconductor heating apparatus having this structure, an end of heater 102 is in contact with holder 101, whereby heat generated from heater 102 is so conducted from the periphery of heater 102 to holder 101 through horizontal support portion 106 that the temperature of the periphery of heater 102 is lower than that at the center of heater 102. A heat insulating material may be inserted between heater 102 and horizontal support portion 106 of holder 101, in order to prevent heater 102 from temperature reduction.

FIG. 2 is a schematic sectional view of another exemplary holder according to the present invention on which a heater is set. The inventive holder 101 comprises a vertical support portion 107 vertically extending from a bottom portion 105. A heater 102 is supported by this vertical support portion 107 and stored in an opening 103 of holder 101, thereby constituting a semiconductor heating apparatus. It follows that heater 102 of this semiconductor heating apparatus heats a semiconductor wafer.

In the semiconductor heating apparatus having this structure, heat generated from heater 102 is conducted to holder 101 through vertical support portion 107, and also transmitted to holder 101 by convection and radiation since the periphery of heater 102 and a side portion 104 of holder 101 are approximate to each other.

Holder 101 shown in FIG. 1 or 2 can be provided with a through-hole, in order to extract various lead wires connected to heater 102. An electrode for supplying power to heater 102 and a temperature measuring device for measuring the temperature of heater 102 may be mounted on portions of heater 102 other than a wafer receiving surface 102a. In this case, therefore, at least one through-hole is formed on side portion 104 or bottom portion 105 of holder 101, so that lead wires of the aforementioned electrode and the aforementioned temperature measuring device can be extracted from holder 101 through the through-hole.

In holder 101 shown in FIG. 1 or 2, as hereinabove described, heat is transmitted from heater 102 to holder 101 to increase the temperature of holder 101. The temperature of heater 102 cannot be uniformized until the temperature of the overall holder 101 reaches an equilibrium state, and hence it takes a long time to uniformize the temperature of the semiconductor wafer.

The inventors have made a deep study, to find that the time for uniformizing the temperature of the semiconductor wafer can be reduced by setting the heat capacity of holder 101 shown in FIG. 1 or 2 to not more than 1.5 times the heat capacity of heater 102 set on holder 101 when heating the semiconductor wafer with heater 102.

The heat capacity of holder 101 is preferably not more than the heat capacity of heater 102 set on holder 101. In this case, the quantity of heat stored in holder 101 is further reduced and the time for bringing the temperature of holder 101 into an equilibrium state can be more reduced, whereby the time for uniformizing the temperature of the semiconductor wafer tends to be further reducible.

The heat capacity of holder 101 is preferably at least 0.2 times the heat capacity of heater 102 set on holder 101. While temperature uniformity of heater 102 may be required also in temperature reduction of heater 102, temperature uniformity of heater 102 tends to be undamaged also in temperature reduction of heater 102 when the heat capacity of holder 101 is at least 0.2 times the heat capacity of heater 102.

In other words, the temperature lowers from the periphery of heater 102 when the temperature of heater 102 lowers, and the heat capacity of holder 101 is so excessively small that the temperature of holder 101 also rapidly lowers if the heat capacity of holder 101 is less than 0.2 times the heat capacity of heater 101. Consequently, temperature reduction on the periphery of heater 102 further accelerates, to further increase the temperature difference between the periphery and the center of heater 102 and increase such a possibility that temperature uniformity of heater 102 is damaged in temperature reduction of heater 102.

When the inventive holder 101 whose heat capacity is controlled in this manner is employed, temperature uniformity of heater 102 set on holder 101 can be improved, and the temperature of heater 102 can be increased/reduced in a short time. Thus, a semiconductor manufacturing apparatus comprising the semiconductor heating apparatus formed by the inventive holder 101 and heater 102 set on this holder 101 is excellent in throughput.

The material constituting the inventive holder 101, not particularly restricted, can be prepared from metal such as stainless, nickel, molybdenum, tungsten, aluminum, iron or copper, for example. In order to improve heat resistance, the inventive holder 101 can be prepared by forming a layer plated with nickel, gold or silver on a surface of the aforementioned metal. In particular, stainless is preferably employed as the material for the inventive holder 101, in consideration of heat resistance and the cost.

The thickness of side portion 104 of the inventive holder 101 not particularly restricted, is preferably set to a value causing neither breakage nor deformation through the heat cycle of heater 102. When holder 101 is made of stainless, the thickness of side portion 104 of the inventive holder 101 is preferably set to at least 0.5 mm, more preferably at least 1 mm, in consideration of a case of supporting a semiconductor wafer having a large diameter of 8 inches or 12 inches. The thickness of bottom portion 105 of the inventive holder 101, receiving the mass of side portion 104 of holder 101 and heater 102, is preferably set to at least 0.8 mm, more preferably at least 1.5 mm.

Heater 102 is prepared from metal or ceramics, for example. In particular, a ceramics heater forming a small quantity of particles is preferably employed in consideration of the recent progress of refinement of semiconductor wires, and a ceramics heater prepared from ceramics mainly composed of aluminum nitride or silicon carbide having high heat conductivity, silicon nitride strong and resistant against a thermal shock, aluminum oxide requiring a low cost or aluminum oxynitride is preferably employed, for example. In consideration of the balance between the performance and the cost, ceramics mainly composed of aluminum nitride (AlN) is particularly preferably employed for heater 102. In the present invention, the material mainly composing the ceramics occupies at least 50 mass % of the overall ceramics employed for heater 102.

A method of manufacturing heater 102 formed by a ceramics heater prepared from ceramics mainly composed of AlN is now described.

AlN powder forming the raw material preferably has a specific surface area of at least 2 m²/g and not more than 5 m²/g. The sintering property of AlN tends to lower if the specific surface area of the AlN powder is less than 2 m²/g, while the AlN powder tends to so strongly aggregate that the same is hard to handle if the specific surface area of the AlN powder exceeds 5 m²/g.

The content of oxygen in the AlN powder is preferably not more than 2 mass % of the overall AlN powder. If the content of oxygen in the AlN powder exceeds 2 mass % of the overall AlN powder, heat conductivity of an AlN sintered body tends to lower.

The quantity of a metallic impurity, other than aluminum (Al), contained in the AlN powder is preferably not more than 2000 ppm. If the quantity of the metallic impurity, other than aluminum (Al), contained in the AlN powder exceeds 2000 ppm, the heat conductivity of the AlN sintered body tends to lower. In particular, a metallic impurity prepared from a group IVB element such as Si or a group VIII element such as Fe has a high function of reducing the heat conductivity of the AlN sintered body, and hence the content of the group IVB element such as Si or the group VIII element such as Fe is preferably not more than 500 ppm.

AlN is a hardly sintered material, and hence a sintering assistant is preferably added to the AlN powder. The added sintering assistant is preferably prepared from a rare earth element compound. The rare earth element compound reacts with aluminum oxide and aluminum oxynitride present on the surface of the AlN powder during sintering of AlN to prompt densification of the AlN sintered body, and can improve the heat conductivity of the AlN sintered body by removing oxygen reducing the heat conductivity of the AlN sintered body.

The content of the rare earth element compound is preferably at least 0.01 mass % and not more than 5 mass % of the overall AlN powder. If the content of the rare earth element compound is less than 0.01 mass % of the overall AlN powder, it is difficult to obtain a dense AlN sintered body, and the heat conductivity of the AlN sintered body tends to lower. If the content of the rare earth element compound exceeds 5 mass %, the sintering agent is present on the grain boundaries of the AlN sintered body, and the sintering agent present on the grain boundaries are easily etched when the heater is used in a corrosive atmosphere to result in shattering or formation particles. Further, the content of the rare earth element compound is preferably not more than 1 mass % of the overall AlN powder. If the content of the rare earth element compound is not more than 1 mass % of the overall AlN powder, the sintering assistant is not present on the triple points of the grain boundaries and corrosion resistance tends to improve.

The aforementioned rare earth element compound is preferably prepared from an yttrium compound having a remarkable function of removing oxygen in particular. Further, the rare earth element compound can be prepared from an oxide of a rare earth element, a nitride of a rare earth element, a fluoride of a rare earth element or a stearic acid compound of a rare earth element, for example. An oxide of a rare earth element is preferable in a point that the same is easily obtained at a low cost. A stearic acid compound of a rare earth element having high affinity to an organic solvent is preferable in a point that a mixing property is improved when the AlN powder and the sintering assistant are mixed with each other through an organic solvent.

Prescribed quantities of a solvent and a binder are added to and mixed with the aforementioned AlN powder and the sintering assistant. These materials can be mixed with each other by a method employing a ball mill or a method employing an ultrasonic wave, for example. The AlN sintered body can be obtained by forming slurry obtained by this mixing and thereafter sintering the same. Heater 102 can be prepared by post-metallization or co-firing, for example.

Exemplary post-metallization is now described. First, the slurry obtained in the aforementioned manner is granulated by spray drying or the like. Then, the obtained granules are inserted into a mold and press-molded.

The pressure for the press molding is preferably at least 9.8 MPa. If the pressure is less than 9.8 MPa, the obtained molding is generally insufficient in strength and easily broken through handling or the like.

The density of the molding is preferably at least 1.5 g/cm³ and not more than 2.5 g/cm³. If the density of the molding is less than 1.5 g/cm³, the distance between particles of the AlN powder is so relatively increased that sintering is hard to progress. If the density of the molding exceeds 2.5 g/cm³, it is difficult to sufficiently remove the binder from the molding in a subsequent degreasing step, and hence it is difficult to obtain a dense AlN sintered body.

Then, decreasing is performed by heating the molding in non-oxidative atmosphere gas. The non-oxidative atmosphere gas is preferably prepared from nitrogen or argon, for example. If the molding is degreased in an oxidative atmosphere such as the atmosphere, the surface of the AlN powder is so oxidized that the heat conductivity of the AlN sintered body tends to lower.

The temperature for heating the molding in the degreasing step is preferably at least 500° C. and not more than 1000° C. If the temperature for heating the molding is less than 500° C., the binder cannot be sufficiently removed but carbon tends to excessively remain in the degreased molding to hinder sintering in a subsequent sintering step. If the temperature for heating the molding exceeds 1000° C., the quantity of carbon remaining in the degreased molding is so excessively reduced that ability of removing oxygen from an oxide film present on the surface of the AlN powder is reduced and the heat conductivity of the sintered body tends to lower. The quantity of carbon remaining in the degreased molding is preferably not more than 1 mass % of the overall molding. If carbon remains in a quantity exceeding 1 mass % of the overall molding, carbon so hinders sintering that a dense AlN sintered body tends to be unobtainable.

Then, the AlN sintered body is prepared by sintering the molding. This sintering can be performed in non-oxidative atmosphere gas such as nitrogen or argon, for example, at a temperature of at least 1700° C. and not more than 2000° C., for example. At this time, the quantity of moisture contained in the non-oxidative atmosphere gas is preferably at such a level that the dew point is not more than −30° C. If the quantity of moisture is in excess of this level, AlN reacts with the moisture contained in the non-oxidative atmosphere gas during sintering to form an oxynitride, and hence there is a possibility that the heat conductivity of the AlN sintered body lowers. Further, the quantity of oxygen in the non-oxidative atmosphere gas is preferably not more than 0.001 volume % of the overall non-oxidative atmosphere gas. If the quantity of oxygen in the non-oxidative atmosphere gas exceeds 0.001 volume % of the overall non-oxidative atmosphere gas, there is a possibility that the surface of the AlN sintered body is oxidized to reduce the heat conductivity of the AlN sintered body.

A jig employed for sintering is preferably formed by a boron nitride (BN) molding. This BN molding, having sufficient heat resistance with respect to a sintering temperature with solid lubricity on the surface thereof, tends to be capable of reducing friction between the jig and the molding when the molding contracts upon sintering. Consequently, a less strained AlN sintered body can be obtained.

The AlN sintered body obtained in the aforementioned manner can be worked if necessary. If conductive paste is screen-printed in a subsequent step, for example, the surface roughness Ra of the AlN sintered body is preferably not more than 5 μm, particularly preferably not more than 1 μm. If the surface roughness Ra of the AlN sintered body is not more than 5 μm, particularly not more than 1 μm, defects such as bleeding of a pattern or pinholes tend to be hardly caused when a circuit is formed by screen printing. In the present invention, the term “surface roughness Ra” indicates the arithmetic mean roughness Ra defined according to JIS B 0601.

While the surface of the AlN sintered body is preferably polished in order to obtain the aforementioned surface roughness, a screen-printed surface as well as an opposite surface are preferably polished not only in a case of performing screen printing on both surfaces of the AlN sintered body but also in a case of performing screen printing only on a single surface of the AlN sintered body. When only the screen-printed surface is polished, it follows that the unpolished surface supports the sintered body in screen printing. At this time, protrusions or foreign matter may be present on the unpolished surface, and hence fixation of the AlN sintered body may be so unstable that a circuit pattern cannot be rightly drawn in screen printing.

The degree of parallelism of both surfaces of the polished AlN sintered body is preferably not more than 0.5 mm, more preferably not more than 0.1 mm. Dispersion in thickness of conductive paste after screen printing increases if the degree of parallelism of both surfaces of the polished AlN sintered body exceeds 0.5 mm, while dispersion in thickness of the conductive paste tends to particularly decrease if the degree of parallelism is not more than 0.1 mm. In the present invention, the term “degree of parallelism” indicates the degree of parallelism defined according to JIS B 0621. The flatness of the screen-printed surface of the AlN sintered body is preferably not more than 0.5 mm, more preferably not more than 0.1 mm. Dispersion in thickness of the conductive paste after screen printing increases if the flatness of the screen-printed surface of the AlN sintered body exceeds 0.5 mm, while dispersion in thickness of the conductive paste tends to decrease if the flatness is not more than 0.1 mm. In the present invention, the term “flatness” indicates the flatness defined according to JIS B 0621.

An electric circuit is formed on the surface of the AlN sintered body polished in the aforementioned manner by applying the conductive paste by screen printing. The conductive paste can be obtained by mixing metal powder, a binder and a solvent with each other, for example. The metal powder is preferably prepared from tungsten, molybdenum or tantalum, in order to reduce the difference between the thermal expansion coefficients of the conductive paste and AlN. Further, oxide powder can also be added to the conductive paste, in order to improve adhesion strength between the same and AlN. The oxide powder is preferably prepared from at least a single type of powder selected from a group consisting of an oxide of a group IIA element, an oxide of a group IIIA element, Al₂O₃ and SiO₂. In particular, powder of yttrium oxide having extremely excellent wettability with respect to AlN is preferably employed as the oxide powder. The content of the oxide powder is preferably at least 0.1 mass % and not more than 30 mass % of the overall conductive paste. If the content of the oxide powder is less than 0.1 mass % of the overall conductive paste, adhesion strength between the electric circuit and AlN tends to lower. If the content of the oxide powder exceeds 30 mass % of the overall conductive paste, electric resistance of the electric circuit tends to increase.

The thickness of the conductive paste is preferably at least 5 μm and not more than 100 μm after drying. If the thickness of the conductive paste is less than 5 μm, the electric resistance of the electric circuit tends to excessively increase while adhesion strength with respect to AlN tends to lower. When heater circuits (heating element circuits) are formed on the AlN sintered body as the electric circuit, the interval between the heater circuits is preferably set to at least 0.1 mm. If the interval between the heater circuits is less than 0.1 mm, a leakage current may be generated to cause a short circuit when a current is fed to the heater circuits. When heater 102 is used at a temperature of at least 500° C., the interval between the heater circuits is preferably at least 1 mm, more preferably at least 3 mm.

Then, the conductive paste is degreased and thereafter fired for forming the electric circuit. The conductive paste can be degreased by heating the same in non-oxidative atmosphere gas such as nitrogen or argon, for example. The temperature for degreasing the conductive paste is preferably at least 500° C. If the temperature for degreasing the conductive paste is less than 500° C., the binder is so insufficiently removed from the conductive that carbon remains in the electric circuit and forms a carbide of metal in firing, and hence the electric resistance of the electric circuit tends to increase.

The conductive paste is preferably fired in non-oxidative atmosphere gas such as nitrogen or argon at a temperature of at least 1500° C., for example. If the temperature for firing the conductive paste is less than 1500° C., no grain growth of the metal powder progresses in the conductive paste, and hence the electric resistance value of the fired electric circuit tends to increase. The temperature for firing the conductive paste is preferably not in excess of the temperature for sintering AlN. If the conductive paste is fired at a temperature exceeding the temperature for sintering AlN, the sintering assistant etc. contained in AlN starts to volatilize and grain growth of the metal powder in the conductive paste is so prompted that adhesion strength between AlN and the electric circuit tends to lower.

Then, an insulating coating is formed on the electric circuit, in order to ensure insulation of the electric circuit. The insulating coating can be preferably prepared from a material having small reactivity with the electric circuit with thermal expansion coefficient difference of not more than 5.0×10⁻⁶/K between the same and AlN. For example, crystallized glass or AlN can be employed. The insulating coating can be formed by pasting this material, for example, performing screen printing in a prescribed thickness, performing degreasing if necessary and firing the paste at a prescribed temperature.

A plurality of AlN sintered bodies can be stacked with each other if necessary. The AlN sintered bodies are preferably stacked with each other through a bonding agent. The bonding agent can be prepared by adding a compound of a group IIA element or a compound of a group IIIA element, a binder and a solvent to aluminum oxide powder or aluminum nitride powder and pasting the mixture, for example, and this bonding agent is applied to bonded surfaces of the AlN sintered bodies by a technique such as screen printing. The bonding agent is preferably applied in a thickness of at least 5 μm. If the bonding agent is applied in a thickness of less than 5 μm, bonding defects such as pinholes or irregular bonding are easily caused on the bonded portions of the AlN sintered bodies.

The AlN sintered bodies coated with the bonding agent are degreased in non-oxidative atmosphere gas such as nitrogen or argon at a temperature of at least 500° C., for example. Thereafter the AlN sintered bodies are bonded to each other by superposing the AlN sintered bodies with each other, applying a prescribed load thereto and heating the same in non-oxidative atmosphere gas such as nitrogen or argon, for example. The aforementioned load applied after superposing the AlN sintered bodies with each other is preferably at least 5 kPa. If the load is less than 5 kPa, sufficient bond strength tends to be unobtainable between the AlN sintered bodies, and the aforementioned bonding defects are easily caused. The temperature in the aforementioned heating after superposing the AlN sintered bodies with each other is preferably at least 1500° C. If the heating temperature is less than 1500° C., sufficient bond strength is hard to obtain and the aforementioned bonding defects are easily caused.

In the above, molybdenum wires (coils) or meshes (network bodies) of molybdenum or tungsten can be employed as the heater circuits, for example. Heater 102 formed by the AlN sintered body comprising the heater circuits can be prepared by hot-pressing AlN powder in which coils or meshes of molybdenum are embedded, for example. The pressure in hot pressing is preferably at least 0.98 MPa. If the pressure in hot pressing is less than 0.98 MPa, clearances may be so formed between the coils or the meshes of molybdenum and the AlN sintered body that the heater cannot sufficiently exhibit the function thereof.

Exemplary co-firing is now described. First, the slurry obtained in the aforementioned manner is formed into a sheet by doctor blade coating. The slurry is preferably so formed that the thickness of the sheet is not more than 3 mm after drying. If the thickness of the sheet exceeds 3 mm after drying, the quantity of drying shrinkage of the slurry is increased to increase such a probability that the sheet is cracked.

An electric circuit is formed by applying conductive paste onto this sheet by a method such as screen printing. The conductive paste can be prepared from the same one as that described with reference to the aforementioned post-metallization. In co-firing, however, no oxide powder may be added to the conductive paste.

Then, a sheet laminate is formed by stacking the sheet provided with the electric circuit and a sheet provided with no electric circuit. A solvent is applied between the sheets forming the sheet laminate if necessary, and the sheet laminate is heated if necessary. When the sheet laminate is heated, the temperature for heating the same is preferably not more than 150° C. If the sheet laminate is heated to a temperature higher than 150° C., the sheets tend to be remarkably deformed. Then, a pressure is so applied to the sheet laminate that the stacked sheets are integrated with each other. The pressure applied to the sheet laminate is preferably at least 1 MPa and not more than 100 MPa. If the pressure applied to the sheet laminate is less than 1 MPa, the sheets are so insufficiently integrated with each other that these sheets may separate from each other in a subsequent step. If the pressure applied to the sheet laminate exceeds 100 MPa, the quantity of deformation of the sheets tends to excessively increase.

The sheet laminate formed by integrating the sheets with each other is degreased and sintered, similarly to the aforementioned post-metallization. The conditions such as the temperatures for degreasing and sintering the sheet laminate and the carbon content therein are similar to those for the post-metallization. A heater having a plurality of electric circuits can also be easily prepared by printing conductive paste on the plurality of sheets respectively and stacking these sheets with each other. When the electric circuit such as a heater circuit is formed on the outermost layer of the sheet laminate, an insulating coating can be formed on the electric circuit similarly to the case of the aforementioned post-metallization, in order to protect the electric circuit and ensure insulation.

The flatness of wafer receiving surface 102a of heater 102 prepared in the aforementioned manner is preferably not more than 0.5 mm, more preferably not more than 0.1 mm. If the flatness of wafer receiving surface 102a exceeds 0.5 mm, a clearance is easily formed between the semiconductor wafer and wafer receiving surface 102a and heat is so hardly uniformly transmitted from heater 102 to the semiconductor wafer that there is a possibility that temperature uniformity of the semiconductor wafer is remarkably damaged.

The surface roughness Ra of wafer receiving surface 102a is preferably not more than 5 μm, more preferably not more than 1 μm. If the surface roughness Ra of wafer receiving surface 102a is not more than 5 μm, particularly not more than 1 μm, shattering of AlN resulting from friction between wafer receiving surface 102a and the semiconductor wafer placed thereon tend to be suppressible. Shattered grains form particles to exert bad influence on a treatment such as film formation or etching on the semiconductor wafer, and hence shattering is preferably suppressed to the minimum.

The inventive holder 101 may comprise a cooling unit for cooling holder 101 and/or heater 102. In this case, the cooling time for holder 101 and/or heater 102 can be reduced, whereby the throughput tends to improve. A mechanism for performing cooling by introducing a fluid such as gas or a liquid for cooling into a passage provided in the cooling unit, for example, is preferably employed as a cooling mechanism for this cooling unit.

### Second Embodiment

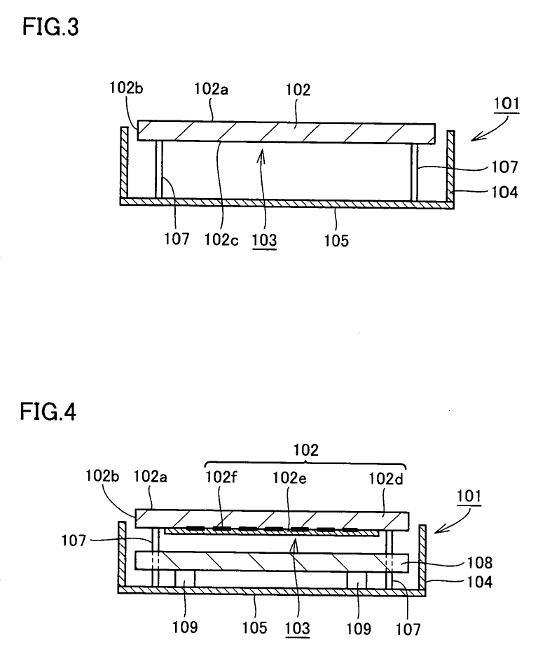

FIG. 3 is a schematic sectional view of still another exemplary holder according to the present invention on which a heater is set. The inventive holder 101 comprises a bottom portion 105, an opening 103 opposed to bottom portion 105 at a prescribed interval, a side portion 104 extending from the periphery of bottom portion 105 toward opening 103 and a vertical support portion 107 vertically extending from bottom portion 105. This vertical support portion 107 supports a heater 102, which in turn is set on the opening of holder 101, thereby constituting a semiconductor heating apparatus. It follows that heater 102 of this semiconductor heating apparatus heats a semiconductor wafer.

Holder 101 shown in FIG. 3 is characterized in that the surface roughness Ra of holder 101 (side portion 104 and bottom portion 105) is not more than 10 μm. Thus, temperature uniformity of heater 102 can be improved by suppressing thermal influence exerted by holder 101 on heater 102.

In other words, it is important to suppress influence exerted by the circumferential environment, such as a peripheral member, of heater 102 on heater 102 to the minimum, in order to improve the temperature uniformity of heater 102. In order to suppress thermal influence from the peripheral environment on heater 102, the way of heat transmission must be taken into consideration.

The way of heat transmission includes three modes, i.e., conduction, convection and radiation, which must be taken into consideration. Thermal influence exerted on heater 102 by conduction is suppressed by minimizing the number of members coming into contact with heater 102. Further, thermal influence on heater 102 by convection is suppressed by suppressing a flow of gas from the periphery of heater 102.

Further, heater 102 is thermally influenced by radiation between the same and holder 101. As shown in FIG. 3, heater 102 is set on opening 103 of holder 101, whereby a side surface 102b and a lower surface 102c included in the surfaces of heater 101 are opposed to holder 101. According to a study made by the inventor, it has been proved that thermal influence exerted on heater 102 by radiation between the same and holder 101 can be suppressed and the temperature uniformity of heater 102 is improved by setting the surface roughness Ra of holder 101 (side portion 104 and bottom portion 105) to not more than 10 μm.

Further, it has been recognized that thermal influence exerted on heater 102 not only by radiation between holder 101 and heater 102 but also by radiation between holder 101 and an external device such as a chamber controlling the atmosphere, for example, can be suppressed by setting the surface roughness Ra of holder 101 (side portion 104 and bottom portion 105) to not more than 10 μm. In addition, it has also been proved that the temperature uniformity of heater 102 is more improved by setting the surface roughness Ra of holder 101 (side portion 104 and bottom portion 105) of holder 101 to not more than 5 μm.

FIG. 4 is a schematic sectional view of a further exemplary holder according to the present invention on which a heater is set. A holder 101 is characterized in that holder 101 comprises an elevation unit 109 on a bottom portion 105 and elevation unit 109 supports a cooling unit 108. A heater 102 is set on an opening 103 of this holder 101 to be supported by a vertical support portion 107, thereby constituting a semiconductor heating apparatus. It follows that heater 102 of this semiconductor heating apparatus heats a semiconductor wafer.

Heater 102 is a ceramics heater constituted of a ceramics member 102d, heater circuits 102f formed on the lower surface of ceramics member 102d and an insulating coating 102e covering these heater circuits 102f.

A cooling mechanism applied to cooling unit 108, not particularly restricted, is preferably a cooling mechanism introducing a fluid such as gas or a liquid for cooling into a passage provided in cooling unit 108. Cooling unit 108, supported by elevation unit 109 such as an air cylinder, freely comes into contact with or separates from the lower surface of heater 102 through vertical movement of elevation unit 109. Cooling unit 108 may include a through-hole for passing vertical support portion 107 therethrough and through-holes for passing an electrode set on heater 102 and a lead wire of a temperature measuring device therethrough.

According to a study made by the inventor, the overall surfaces of heater 102 and cooling unit 108 can be uniformly brought into contact with each other by flattening both of the surface of heater 102 coming into contact with cooling unit 108 and the surface of cooling unit 108 coming into contact with heater 102. In this case, adhesiveness between heater 102 and cooling unit 108 further increases to improve a heat transfer coefficient for improving a cooling rate of cooling unit 108 brought into contact with heater 102 while cooling unit 108 uniformly cools the overall surface of heater 102 coming into contact with cooling unit 108, whereby the temperature uniformity of heater 102 can be improved when cooled by cooling unit 108.

The sum of the flatness of the surface of heater 102 coming into contact with cooling unit 108 and the flatness of the surface of cooling unit 108 coming into contact with heater 102 is preferably not more than 0.8 mm, more preferably not more than 0.4 mm. In this case, the temperature uniformity of heater 102 tends to be further improvable when cooled with cooling unit 108.

In heater 102 having the structure shown in FIG. 4, the sum of the flatness of the surface of insulating coating 102e coming into contact with cooling unit 108 and the flatness of the surface of cooling unit 108 coming into contact with insulating coating 102e is preferably not more than 0.8 mm, more preferably not more than 0.4 mm.

A method such as well-known lap polishing or grinding with a grindstone, for example, can be employed as a method of flattening the surface of heater 102 coming into contact with cooling unit 108 and the surface of cooling unit 108 coming into contact with heater 102. Each of the surface roughness Ra of the flattened surface of heater 102 coming into contact with cooling unit 108 and the surface roughness Ra of the flattened surface of cooling unit 108 coming into contact with heater 102 is preferably not more than 5 μm. When this surface roughness Ra is set to not more than 5 μm, adhesiveness between cooling unit 108 and heater 102 is so improved that the temperature uniformity of heater 102 and the cooling rate tend to improve.

In particular, the surface roughness Ra of the surface of heater 102 coming into contact with cooling unit 108 is so reduced as to reduce emissivity of the surface. If the emissivity of the surface is reduced, the quantity of heat radiation from the surface is so reduced that power for heating heater 102 can be reduced. If the surface of heater 102 coming into contact with cooling unit 108 is made of ceramics and this surface is rough, ceramics grains may be remarkably shattered by friction upon contact with cooling unit 108 to form particles exerting bad influence on the quality of the semiconductor wafer. Therefore, the surface roughness Ra of the surface of heater 102 coming into contact with cooling unit 108 is preferably not more than 1 μm.

When heater 102 having the structure shown in FIG. 4 is excessively worked in order to flatten the surface of insulating coating 102e coming into contact with cooling unit 108, the thickness of insulating coating 102e may be so reduced that heater circuits 102f are exposed to cause a short circuit. While the thickness of insulating coating 102e may be increased in order to avoid occurrence of such a problem, insulating coating 102e generally has small heat conductivity and hence the cooling rate with cooling unit 108 tends to lower due to increased thermal resistance if the thickness of insulating coating 102e is large. Therefore, the thickness of flattened insulating coating 102e is preferably set to at least 15 μm and not more than 500 μm. If the thickness of flattened insulating coating 102e is dispersed, thermal resistance varies to disperse the cooling rate, and hence the difference between the maximum and minimum values of the thickness of flattened insulating coating 102e is preferably not more than 200 μm.

The remaining description is similar to that of the first embodiment.

### Third Embodiment

FIG. 5 is a schematic sectional view of a further exemplary holder according to the present invention on which a heater is set. The inventive holder 101 is constituted of a bottom portion 105, an opening 103 opposed to bottom portion 105 at a prescribed interval, a side portion 104 extending from the periphery of bottom portion 105 toward opening 103 and a horizontal support portion 106 extending from an end of side portion 104 toward opening 103 in parallel with bottom portion 105.

A heater 102 is set on opening 103 of holder 101 to be supported by horizontal support portion 106, thereby constituting a semiconductor heating apparatus. A semiconductor wafer is set on a wafer receiving surface 102a of heater 102 of this semiconductor heating apparatus, and it follows that heater 102 heats the semiconductor wafer.

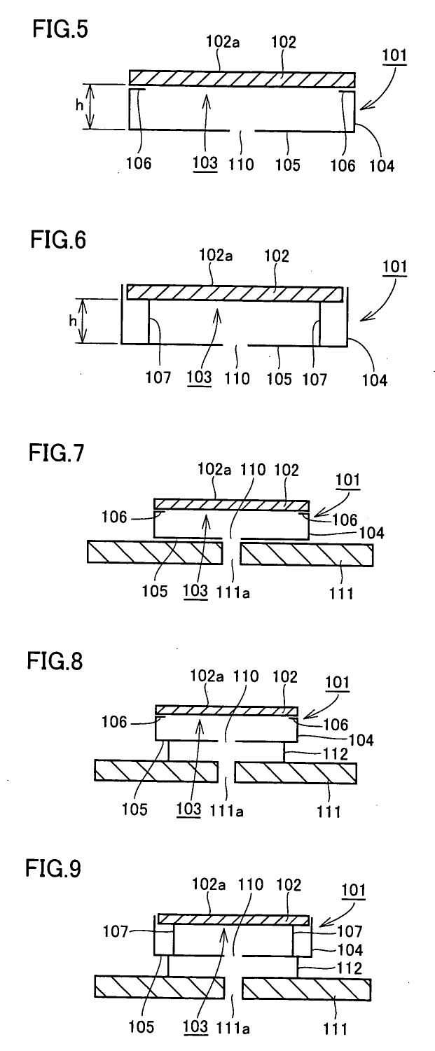

FIG. 6 is a schematic sectional view of a further exemplary holder according to the present invention on which a heater is set. The inventive holder 101 comprises a vertical support portion 107 vertically extending from a bottom portion 105. This vertical support portion 107 supports a heater 102, which in turn is set on an opening 103 of holder 101, thereby constituting a semiconductor heating apparatus. It follows that heater 102 of this semiconductor heating apparatus heats a semiconductor wafer.

Holder 101 shown in each of FIGS. 5 and 6 is characterized in that a circular through-hole 110 is formed on bottom surface 105 of holder 101, and the diameter of this through-hole 110 is smaller than the height h of the holder. While through-hole 110 is provided for extracting various lead wires connected to heater 102, it follows that external air flows into holder 101 through this through-hole 110, rises in holder 101 and comes into contact with heater 102. At this time, the air flowing into holder 101 is mixed with air in holder 101, and heated before coming into contact with heater 102. If through-hole 110 has a large diameter, however, the flow of the air flowing into holder 101 from through-hole 110 so enlarges that insufficiently heated air easily comes into contact with heater 102. Consequently, the temperature of heater 102 in the portion coming into contact with the insufficiently heated air locally lowers, and it follows that the temperature uniformity of heater 102 is remarkably damaged.

In the inventive holder 101, therefore, the diameter of through-hole 110 is set below the height h of the holder. When the diameter of through-hole 110 is below the height h of the holder, i.e., when the area of through-hole 11 is below the area of a circle having a diameter corresponding to the height of the holder h, the quantity of air flowing from through-hole 110 into holder 101 is so suppressed that insufficiently heated air hardly comes into contact with heater 102, whereby the temperature uniformity of the heater is improved. According to the present invention, the term “height h of the holder” indicates the minimum distance between the surface of bottom portion 105 of holder 101 closer to opening 103 and heater 102 set on opening 103.

While the case where the shape of through-hole 110 is circular has been described in the above, the shape of through-hole 110 is not particularly restricted but may be a polygonal shape such as a triangle or a square. While the case where through-hole 110 is formed on bottom portion 105 of holder 101 has been described in the above, through-hole 110 may be formed on side portion 104 of holder 101.

In a case of forming a plurality of through-holes 110 in holder 101, through-holes 110 are preferably formed to satisfy the relation A×B≧1, and through-holes 110 are preferably formed to satisfy the relation A×B≧3, assuming that A (mm) represents the minimum distance between through-holes 110 and B (mm) represents the thickness of holder 101. When the thickness B of holder 101 is 1 mm in the portions provided with through-holes 110, for example, through-holes 110 are preferably so formed as to ensure the minimum distance A of at least 1 mm between through-holes 110. When A×B<1, portions of holder 101 located between through-holes 110 are so deformed by the heat cycle of heater 102 that heater 102 set on holder 101 easily backlashes or inclines and there is a possibility that the semiconductor wafer set on wafer receiving surface 102a is inclined. When the relation A×B≧3 is satisfied, this problem tends to hardly arise.

When the inventive holder 101 is set on a support 111 as shown in FIG. 7, a through-hole 111a is also formed on a portion of support 111 corresponding to a through-hole 110 of a bottom portion 105 of holder 101 so that the aforementioned lead wires can be extracted through through-holes 110 and 111a.

In this case, however, holder 101 and support 111 are in contact with each other, and hence heat generated from a heater 102 is transmitted to support 111 through holder 101, the temperature of the overall apparatus easily increases and power consumption in heater 102 also increases. If holder 101 and support 111 are partially in contact with each other, the temperature of holder 101 is so easily dispersed that there is also a possibility that the temperature uniformity of heater 102 is remarkably damaged.

Therefore, it is preferable to form a space between a holder 101 and a support 111 when holder 101 is set on support 111, by setting a support member 112 on a bottom portion 105 of holder 101 as shown in each of FIGS. 8 and 9, for example. In this case, the overall bottom portion 105 of holder 101 is not in contact with support 111 so that the temperature of bottom portion 105 of holder 101 is hardly dispersed, whereby the temperature uniformity of heater 102 can be improved. The length of support member 112 is preferably at least 1 mm, in order to improve the temperature uniformity of heater 102.

The remaining description is similar to that of the first embodiment.

### EXPERIMENTAL EXAMPLE 1

An AlN substrate having a diameter of 330 mm, a thickness of 10 mm and a yttrium content of 0.6 mass % in terms of an oxide was prepared. Heat circuits were formed by screen-printing conductive paste on one surface of this AlN substrate. The conductive paste was prepared by adding 1 mass % of yttria (Y₂O₃) to tungsten powder, further adding an organic solvent and a binder thereto and pasting the mixture. A heater substrate was prepared by degreasing the aforementioned screen-printed AlN substrate in a nitrogen atmosphere at 800° C. and thereafter firing the same in a nitrogen atmosphere at 1800° C.

Then, paste was prepared by adding 1 part by mass of Y₂O₃ to 100 parts by mass of AlN powder and further adding an organic solvent and a binder thereto. This paste was applied to portions of the aforementioned heater substrate other than an electrode mounting portion in a thickness of 100 μm, and thereafter dried. A heater was prepared by degreasing the heater substrate in a nitrogen atmosphere at 800° C. after drying the paste and thereafter firing the same in a nitrogen atmosphere at 1800° C. A wafer receiving surface of the heater was so polished that the flatness was not more than 10 μm, and spot-faced bores of 0.9 mm in depth were formed in 10 portions. Then, alumina balls of 1 mm in diameter were set in the spot-faced bores respectively. At this time, the heat capacity of the heater was 2031 J/K.

Holders 101 of samples Nos. 1 to 16 shown in Table 1, each having the shape shown in FIG. 1, prepared from stainless or copper having surfaces plated with nickel were prepared. Holders 101 of the samples Nos. 1 to 16 were prepared to be different in heat capacity from each other, and the height of each holder 101 was 40 mm while the length of each horizontal support portion 106 was 10 mm. Holders 101 of the samples Nos. 1 to 8 are made of stainless, while holders 101 of the samples Nos. 9 to 16 are made of copper having surfaces plated with nickel.

The heater prepared in the aforementioned manner was set on horizontal support portion 106 of holder 101 according to each of the samples Nos. 1 to 16, as shown in FIG. 1. A semiconductor wafer was set on wafer receiving surface 102a of heater 102 and the temperature of heater 102 was increased to 150° C., for measuring temperature uniformity of the semiconductor wafer upon a lapse of one minute after the temperature of the semiconductor wafer reached 150° C. Further, temperature distribution of the semiconductor wafer was measured upon a lapse of five minutes after stopping power supply to heater 102. Table 1 shows the results.

Referring to Table 1, each column of (Heat Capacity of Holder)/(Heat Capacity of Heater) describes a value obtained by dividing the heat capacity of holder 101 according to each of the samples Nos. 1 to 16 by the heat capacity of heater 102. Referring to Table 1, further, each column of “Temperature Uniformity of Semiconductor Wafer” describes the difference between the maximum and minimum temperatures in the semiconductor wafer upon a lapse of one minute after the temperature reached 150° C.

TABLE 1

| | | | | | Temperature | Temperature |
|---|---|---|---|---|---|---|
| | Holder | | | (Heat Capacity | Uniformity of | Distribution of |
| | | | Heat | of Holder)/ | Semiconductor | Semiconductor |
| Sample | | Thickness | Capacity | (Heat Capacity | Wafer | Wafer |
| No. | Material | (mm) | (J/K) | of Heater) | (° C.) | (° C.) |
| 1 | stainless | 7.0 | 3598 | 1.77 | 1.04 | 141 ± 1.2 |
| 2 | stainless | 5.9 | 3033 | 1.49 | 0.83 | 139 ± 0.9 |
| 3 | stainless | 3.9 | 2005 | 0.99 | 0.47 | 136 ± 0.6 |
| 4 | stainless | 2.0 | 1028 | 0.51 | 0.36 | 134 ± 0.5 |
| 5 | stainless | 1.5 | 771 | 0.38 | 0.32 | 133 ± 0.5 |
| 6 | stainless | 1.0 | 514 | 0.25 | 0.30 | 132 ± 0.6 |
| 7 | stainless | 0.8 | 411 | 0.20 | 0.29 | 132 ± 0.8 |
| 8 | stainless | 0.5 | 257 | 0.13 | 0.29 | 131 ± 1.1 |
| 9 | copper (plated | 8.0 | 3654 | 1.80 | 1.10 | 140 ± 1.2 |
| | with Ni) | | | | | |
| 10 | copper (plated | 6.5 | 2969 | 1.46 | 0.88 | 138 ± 0.9 |
| | with Ni) | | | | | |
| 11 | copper (plated | 4.25 | 1942 | 0.96 | 0.49 | 136 ± 0.7 |
| | with Ni) | | | | | |
| 12 | copper (plated | 3.0 | 1370 | 0.67 | 0.39 | 135 ± 0.6 |
| | with Ni) | | | | | |
| 13 | copper (plated | 2.0 | 914 | 0.45 | 0.35 | 134 ± 0.7 |
| | with Ni) | | | | | |
| 14 | copper (plated | 1.5 | 685 | 0.34 | 0.33 | 133 ± 0.8 |
| | with Ni) | | | | | |
| 15 | copper (plated | 1.0 | 457 | 0.22 | 0.31 | 132 ± 0.9 |
| | with Ni) | | | | | |
| 16 | copper (plated | 0.7 | 320 | 0.16 | 0.29 | 131 ± 1.1 |
| | with Ni) | | | | | |

As shown in Table 1, it has been confirmable that the temperature uniformity of the semiconductor wafer upon a lapse of one minute after the temperature of the semiconductor wafer reached 150° C. was improved and dispersion of temperature distribution of the semiconductor wafer upon a lapse of five minutes after stopping power supply to the heater was also reducible in the case of employing the holder according to each of the samples Nos. 2 to 8 exhibiting the heat capacity of not more than 1.5 times the heat capacity of the heater, as compared with the case of employing the holder according to the sample No. 1 exhibiting the heat capacity exceeding 1.5 times the heat capacity of the heater.

As shown in Table 1, further, it has been confirmable that the temperature uniformity of the semiconductor wafer upon a lapse of one minute after the temperature of the semiconductor wafer reached 150° C. was improved and dispersion of temperature distribution of the semiconductor wafer upon a lapse of five minutes after stopping power supply to the heater was also reducible in the case of employing the holder according to each of the samples Nos. 10 to 16 exhibiting the heat capacity of not more than 1.5 times the heat capacity of the heater, as compared with the case of employing the holder according to the sample No. 9 exhibiting the heat capacity in excess of 1.5 times the heat capacity of the heater.

### EXPERIMENTAL EXAMPLE 2

Holders 101 of samples Nos. 17 to 32 shown in Table 2, each having the shape shown in FIG. 2, prepared from stainless or copper having surfaces plated with nickel were prepared. Holders 101 of the samples Nos. 17 to 32 were prepared to be different in heat capacity from each other, and the height of side portion 104 of each holder 101 was 45 mm while the diameter of bottom portion 105 was 340 mm. Holders 101 of the samples Nos. 17 to 24 are made of stainless, while holders 101 of the samples Nos. 25 to 32 are made of copper having surfaces plated with nickel.

The heater employed in Experimental Example 1 was set on horizontal support portion 107 of holder 101 according to each of the samples Nos. 17 to 32, as shown in FIG. 2. A semiconductor wafer was set on wafer receiving surface 102a of heater 102 and the temperature of heater 102 was increased to 150° C., for measuring temperature uniformity of the semiconductor wafer upon a lapse of one minute after the temperature of the semiconductor wafer reached 150° C. Further, temperature distribution of the semiconductor wafer was measured upon a lapse of five minutes after stopping power supply to heater 102. Table 2 shows the results. The notation in Table 2 is based on Table 1.

TABLE 2

| | | | | | Temperature | Temperature |
|---|---|---|---|---|---|---|
| | Holder | | | (Heat Capacity | Uniformity of | Distribution of |
| | | | Heat | of Holder)/ | Semiconductor | Semiconductor |
| Sample | | Thickness | capacity | (Heat Capacity | Wafer | Wafer |
| No. | Material | (mm) | (J/K) | of Heater) | (° C.) | (° C.) |
| 17 | stainless | 7.0 | 3652 | 1.89 | 1.11 | 143 ± 1.2 |
| 18 | stainless | 5.5 | 2870 | 1.48 | 0.89 | 139 ± 0.9 |
| 19 | stainless | 3.5 | 1919 | 0.94 | 0.45 | 136 ± 0.6 |
| 20 | stainless | 2.0 | 1096 | 0.54 | 0.37 | 134 ± 0.5 |
| 21 | stainless | 1.5 | 822 | 0.40 | 0.34 | 133 ± 0.5 |
| 22 | stainless | 1.0 | 545 | 0.25 | 0.31 | 132 ± 0.6 |
| 23 | stainless | 0.8 | 438 | 0.22 | 0.30 | 132 ± 0.7 |
| 24 | stainless | 0.5 | 274 | 0.13 | 0.29 | 131 ± 1.1 |
| 25 | copper (plated | 7.0 | 3410 | 1.68 | 1.05 | 139 ± 1.1 |
| | with Ni) | | | | | |
| 26 | copper (plated | 6.0 | 2923 | 1.44 | 0.85 | 137 ± 0.9 |
| | with Ni) | | | | | |
| 27 | copper (plated | 4.0 | 1949 | 0.96 | 0.49 | 136 ± 0.6 |
| | with Ni) | | | | | |
| 28 | copper (plated | 3.0 | 1461 | 0.72 | 0.41 | 135 ± 0.5 |
| | with Ni) | | | | | |
| 29 | copper (plated | 2.0 | 974 | 0.48 | 0.36 | 134 ± 0.7 |
| | with Ni) | | | | | |
| 30 | copper (plated | 1.5 | 730 | 0.36 | 0.34 | 133 ± 0.8 |
| | with Ni) | | | | | |
| 31 | copper (plated | 1.0 | 487 | 0.24 | 0.32 | 132 ± 0.9 |
| | with Ni) | | | | | |
| 32 | copper (plated | 0.7 | 341 | 0.17 | 0.30 | 131 ± 1.1 |
| | with Ni) | | | | | |

As shown in Table 2, it has been confirmable that the temperature uniformity of the semiconductor wafer upon a lapse of one minute after the temperature of the semiconductor wafer reached 150° C. was improved and dispersion of temperature distribution of the semiconductor wafer upon a lapse of five minutes after stopping power supply to the heater was also reducible in the case of employing the holder according to each of the samples Nos. 18 to 24 exhibiting the heat capacity not more than 1.5 times the heat capacity of the heater, as compared with the case of employing the holder according to the sample No. 17 exhibiting the heat capacity exceeding 1.5 times the heat capacity of the heater.

As shown in Table 2, further, it has been confirmable that the temperature uniformity of the semiconductor wafer upon a lapse of one minute after the temperature of the semiconductor wafer reached 150° C. was improved and dispersion of temperature distribution of the semiconductor wafer upon a lapse of five minutes after stopping power supply to the heater was also reducible in the case of employing the holder according to each of the samples Nos. 26 to 32 exhibiting the heat capacity of not more than 1.5 times the heat capacity of the heater, as compared with the case of employing the holder according to the sample No. 25 exhibiting the heat capacity in excess of 1.5 times the heat capacity of the heater.

### EXPERIMENTAL EXAMPLE 3

An AlN substrate having a diameter of 330 mm and a thickness of 12 mm was prepared. Heater circuits were formed by screen-printing conductive paste on one surface of this AlN substrate. The conductive paste was prepared by adding an organic solvent and a binder to tungsten powder and pasting the mixture. A heater substrate was prepared by degreasing the aforementioned screen-printed AlN substrate and thereafter firing the same.

Then, paste was prepared by adding an organic solvent and a binder to glass powder. This paste was applied to portions of the aforementioned heater substrate other than an electrode mounting portion by screen printing, and thereafter dried. A heater was prepared by degreasing the heater substrate after drying the paste and thereafter firing the same.

Holders 101 of samples Nos. 33 to 38 of stainless show in Table 3 each having the shape shown in FIG. 3 were prepared. Holders 101 of the samples Nos. 33 to 38 were so worked that the surface roughness values Ra of all of the inner peripheral surfaces (inner peripheral surfaces of side portions 104 and surfaces of bottom portions 105 closer to openings 103) and the outer peripheral surfaces (outer peripheral surfaces of side portions 104 and surfaces of bottom portions 105 opposite to openings 103) of holders 101 were 1.2 μm (sample No. 33), 3.1 μm (sample No. 34), 4.5 μm (sample No. 35), 6.2 μm (sample No. 36), 8.5 μm (sample No. 37) and 10.4 μm (sample No. 38) respectively. Holder 101 according to each of the samples Nos. 33 to 38 had an outer diameter of 350 mm, an inner diameter of 335 mm and a height of 35 mm.

Heater 102 prepared in the aforementioned manner was set on vertical support portion 107 of holder 101 according to each of the samples Nos. 33 to 38, for measuring temperature uniformity of heater 102. The temperature uniformity of heater 102 was measured by heating heater 102 to 150° C., 200° C. and 250° C. respectively with a 17-point wafer thermometer and measuring the maximum and minimum temperatures of heater 102 upon a lapse of three minutes after reaching each temperature, for evaluating the difference therebetween as the temperature uniformity of heater 102. Table 3 shows the results.

TABLE 3

| | Surface | | | |
|---|---|---|---|---|
| Sample | Roughness Ra of | Temperature Uniformity of Heater | | |
| No. | Holder (μm) | 150° C. | 200° C. | 250° C. |
| 33 | 1.2 | 0.73 | 1.02 | 1.59 |
| 34 | 3.1 | 0.75 | 1.02 | 1.62 |
| 35 | 4.5 | 0.78 | 1.03 | 1.62 |
| 36 | 6.2 | 0.89 | 1.17 | 1.84 |
| 37 | 8.5 | 0.90 | 1.19 | 1.88 |
| 38 | 10.4 | 1.32 | 1.67 | 2.01 |

As shown in Table 3, it has been confirmed that the temperature uniformity of the heater was improved in the case of employing the holder according to each of the samples Nos. 33 to 37 having the surface roughness Ra of not more than 10 μm as compared with the case of employing the holder according to the sample No. 38 having the surface roughness Ra exceeding 10 μm.

### EXPERIMENTAL EXAMPLE 4

First, a heater was prepared similarly to Experimental Example 1. Then, stainless steel sheets of 2 mm in thickness were cut into prescribed shapes, thereby preparing holders 101 of samples Nos. 39 to 52 shown in Table 4 each having the shape shown in FIG. 5 or FIG. 6. The heights of holders 101 according to the samples Nos. 39 to 52 were 50 mm respectively, the diameters of holders 101 according to the samples Nos. 39 to 45 were 330 mm respectively, and the diameters of holders 101 according to the samples Nos. 46 to 52 were 350 mm.

Three circular through-holes 110 in total for lead wires connected to an electrode for supplying power to heater 102 and for a temperature measuring device were formed in bottom portion 105 of holder 101 according to each of the samples Nos. 39 to 52. At this time, the diameters of through-holes 110, the minimum distance between through-holes 110 and the minimum distance A between through-holes 110×the thickness B (mm) of holder 101 were varied as shown in Table 4 respectively.

Heater 102 prepared in the aforementioned manner was set on opening portion 103 of holder 101 according to each of the samples Nos. 39 to 52, and a semiconductor wafer comprising a resistance thermometer sensor was set on wafer receiving surface 102a of heater 102. The semiconductor wafer was heated with heater 102 so that the average temperature thereof was 150° C., for evaluating the temperature uniformity of the semiconductor wafer. Table 4 shows the results.

After evaluating the temperature uniformity of the semiconductor wafer, a durability test was performed by repeating temperature change between the room temperature and 200° C. 100 times. Then, the semiconductor wafer was heated again so that the average temperature thereof was 150° C., for evaluating the temperature uniformity of the semiconductor wafer. Table 4 also shows the results.

Each column of “Temperature Uniformity before Durability Test” describes the difference between the maximum and minimum temperatures of the semiconductor wafer upon evaluation of the temperature uniformity before the durability test. Further, each column of “Temperature Uniformity after Durability Test” describes the difference between the maximum and minimum temperatures of the semiconductor wafer upon evaluation of the temperature uniformity after the durability test.

TABLE 4

| | | | Minimum | | Temperature | Temperature |
|---|---|---|---|---|---|---|
| | | | Distance | | Uniformity | Uniformity |
| | | Diameter of | Between | | before | after Durability |
| Sample | Shape of | Through-Hole | Through-Holes | | Durability Test | Test |
| No. | Holder | (mm) | (mm) | A × B | (° C.) | (° C.) |
| 39 | | 50 | 0.5 | 1.0 | 0.75 | 0.76 |
| 40 | | 20 | 0.5 | 1.0 | 0.63 | 0.63 |
| 41 | | 5 | 0.5 | 1.0 | 0.59 | 0.59 |
| 42 | | 5 | 2 | 4 | 0.50 | 0.50 |
| 43 | | 20 | 0.3 | 0.6 | 1.10 | 1.32 |
| 44 | | 55 | 2 | 4 | 1.21 | 1.22 |
| 45 | | 5 | 10 | 20 | 0.35 | 0.35 |
| 46 | | 50 | 0.5 | 1.0 | 0.70 | 0.71 |
| 47 | | 20 | 0.5 | 1.0 | 0.59 | 0.59 |
| 48 | | 5 | 0.5 | 1.0 | 0.53 | 0.53 |
| 49 | | 5 | 2 | 4 | 0.48 | 0.48 |
| 50 | | 20 | 0.3 | 0.6 | 1.03 | 1.21 |
| 51 | | 55 | 2 | 4 | 1.13 | 1.19 |
| 52 | | 5 | 10 | 20 | 0.29 | 0.29 |

As shown in Table 4, it has been confirmed that the temperature uniformity of the semiconductor wafer was more improved before and after the durability test in the case of employing the holder according to each of the samples Nos. 39 to 42 and 45 satisfying the requirements that (1) the diameter of the through-holes is not more than the height (50 mm) of the holder (i.e., the area of the through-holes is not more than the area of a circle having a diameter corresponding to the height of the semiconductor holder) and (2) A×B≧1 as compared with the case of employing the holders according to the samples Nos. 43 and 44 not satisfying the aforementioned requirement (1) or (2).

As shown in Table 4, it has also been confirmed that the temperature uniformity of the semiconductor wafer was more improved before and after the durability test in the case of employing the holder according to each of the samples Nos. 46 to 49 and 52 satisfying the aforementioned requirements (1) and (2) as compared with the case of employing the holders according to the samples Nos. 50 and 51 not satisfying the requirement (1) or (2).

As shown in Table 4, it has further been confirmed that the temperature uniformity of the semiconductor wafer remained substantially identical before and after the durability test and hence the holder was also excellent in durability in the case of employing the holder according to each of the samples Nos. 39 to 42, 45 to 49 and 52.

### EXPERIMENTAL EXAMPLE 5

Holder 101 according to each of samples Nos. 53 to 66 shown in Table 5 having the shape shown in FIG. 5 or FIG. 6 was prepared similarly to Experimental Example 4, except that the thickness B (mm) of the holder of stainless was changed to 4 mm while varying the minimum distance between the through-holes. The temperature uniformity of a semiconductor wafer before and after a durability test was evaluated with holder 101 according to each of the samples Nos. 53 to 66, similarly to Experimental Example 4. Table 5 shows the results. The notation in Table 5 is based on Table 4.

TABLE 5

| | | | Minimum | | Temperature | Temperature |
|---|---|---|---|---|---|---|
| | | | Distance | | Uniformity | Uniformity |
| | | Diameter of | between | | before | after Durability |
| Sample | Shape of | Through-Hole | Through-Holes | | Durability Test | Test |
| No. | Holder | (mm) | (mm) | A × B | (° C.) | (° C.) |
| 53 | | 50 | 0.25 | 1.0 | 0.73 | 0.73 |
| 54 | | 20 | 0.25 | 1.0 | 0.61 | 0.61 |
| 55 | | 5 | 0.25 | 1.0 | 0.57 | 0.57 |
| 56 | | 5 | 1 | 4 | 0.49 | 0.49 |
| 57 | | 20 | 0.2 | 0.8 | 1.03 | 1.12 |
| 58 | | 55 | 1 | 4 | 1.19 | 1.19 |
| 59 | | 5 | 5 | 20 | 0.37 | 0.37 |
| 60 | | 50 | 0.25 | 1.0 | 0.69 | 0.69 |
| 61 | | 20 | 0.25 | 1.0 | 0.58 | 0.58 |
| 62 | | 5 | 0.25 | 1.0 | 0.51 | 0.51 |
| 63 | | 5 | 1 | 4 | 0.47 | 0.47 |
| 64 | | 20 | 0.2 | 0.8 | 0.99 | 1.05 |
| 65 | | 55 | 1 | 4 | 1.11 | 1.16 |
| 66 | | 5 | 5 | 20 | 0.28 | 0.28 |

As shown in Table 5, it has been confirmed that the temperature uniformity of each semiconductor wafer before and after the durability test is more improved in the case of employing the holder according to each of the samples Nos. 53 to 56 satisfying the requirements that (1) the diameter of the through-holes is not more than the height (50 mm) of the holder (i.e., the area of the through-holes is not more than the area of a circle having a diameter corresponding to the height of the semiconductor heater holder) and (2) A×B≧1 as compared with the case of employing the holders according to the samples Nos. 57 and 58 not satisfying the aforementioned requirement (1) or (2).

As shown in Table 5, it has also been confirmed that the temperature uniformity of the semiconductor wafer was more improved before and after the durability test in the case of employing the holder according to each of the samples Nos. 60 to 63 and 66 satisfying the aforementioned requirements (1) and (2) as compared with the case of employing the holders according to the samples Nos. 64 and 65 not satisfying the requirement (1) or (2).

As shown in Table 5, it has further been confirmed that the value of the temperature uniformity of the semiconductor wafer remained substantially unchanged before and after the durability test and hence the holder was also excellent in durability in the case of employing the holder according to each of the samples Nos. 53 to 56, 59 to 63 and 66.

### EXPERIMENTAL EXAMPLE 6

A stainless steel bar of 4 mm in diameter was bonded to bottom portion 105 of holder 101 according to each of the samples Nos. 45, 52, 59 and 66 by welding as support member 112, and each of the aforementioned holders 101 was set on support 111 as shown in FIG. 8 or FIG. 9. A clearance of 15 mm was formed between holder 101 and support 111.

Heater 102 was set on opening 103 of each of the aforementioned holders 101 similarly to Experimental Example 4, for evaluating temperature uniformity of each semiconductor wafer before and after a durability test similarly to Experimental Example 4.

Consequently, the temperature uniformity of the semiconductor wafer before the durability test was 0.28° C. (0.35° C. in Experimental Example 4) in the case of employing the holder according to the sample No. 45, and the temperature uniformity of the semiconductor wafer before the durability test was 0.22° C. (0.29° C. in Experimental Example 4) in the case of employing the holder according to the sample No. 52. Further, the temperature uniformity of the semiconductor wafer before the durability test was 0.29° C. (0.37° C. in Experimental Example 4) in the case of employing the holder according to the sample No. 59, and the temperature uniformity of the semiconductor wafer before the durability test was 0.20° C. (0.28° C. in Experimental Example 4) in the case of employing the holder according to the sample No. 66.

Therefore, it has been confirmed that the temperature uniformity of the semiconductor wafer was improved before the durability test in the case of forming the clearance between holder 101 and support 11 in each of the samples Nos. 45, 52, 59 and 66. Further, the temperature uniformity of the semiconductor wafer after the durability test was not reduced below the temperature durability of the semiconductor wafer before the durability test, and it has been confirmed that the holders according to the samples Nos. 45, 52, 59 and 66 are excellent in durability.

The clearance between holder 101 and support 111 in the aforementioned sample No. 45 was varied as shown in Table 6, for evaluating temperature uniformity of the semiconductor wafer before and after the durability test similarly to Experimental Example 4. Table 6 shows the results.

TABLE 6

| Clearance between | Temperature Uniformity | Temperature Uniformity |
|---|---|---|
| Holder and Support | before Durability Test | after Durability Test |
| (mm) | (° C.) | (° C.) |
| 0 | 0.29 | 0.29 |
| 0.5 | 0.27 | 0.27 |
| 1.0 | 0.23 | 0.23 |
| 5.0 | 0.23 | 0.23 |
| 15 | 0.22 | 0.22 |

As shown in Table 6, the uniformity of the semiconductor wafer after the durability test was not reduced as compared with the temperature uniformity of the semiconductor wafer before the durability test in the case of employing the holder according to the sample No. 45 regardless of presence/absence of the clearance between the holder and the support, and it has been confirmed that the holder according to the sample 45 is excellent in durability.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor heater holder for setting a heater for heating a semiconductor, having an opening, wherein the heat capacity of said semiconductor heater holder is not more than 1.5 times the heat capacity of said heater.

2. The semiconductor heater holder according to claim 1, wherein the heat capacity of said semiconductor heater holder is not more than the heat capacity of said heater.

3. The semiconductor heater holder according to claim 1, wherein the heat capacity of said semiconductor heater holder is at least 0.2 times the heat capacity of said heater.

4. The semiconductor heater holder according to claim 1, wherein said heater is a ceramics heater prepared from ceramics mainly composed of aluminum nitride, silicon nitride, silicon carbide, aluminum oxide or aluminum oxynitride.

5. The semiconductor heater holder according to claim 4, wherein said heater is a ceramics heater prepared from ceramics mainly composed of aluminum nitride.

6. The semiconductor heater holder according to claim 1, wherein said semiconductor heater holder is made of metal.

7. The semiconductor heater holder according to claim 1, having a cooling unit.

8. The semiconductor heater holder according to claim 7, wherein a fluid is introduced into said cooling unit.

9. A semiconductor manufacturing apparatus comprising the semiconductor heater holder according to claim 1.

10. A semiconductor heater holder for setting a heater for heating a semiconductor, having an opening, wherein the surface roughness Ra of said semiconductor heater holder is not more than 10 μm.

11. The semiconductor heater holder according to claim 10, wherein the surface roughness Ra of said semiconductor heater holder is not more than 5 μm.

12. The semiconductor heat holder according to claim 10, wherein said heater is a ceramics heater prepared from ceramics mainly composed of aluminum nitride, silicon nitride, silicon carbide, aluminum oxide or aluminum oxynitride.

13. The semiconductor heater holder according to claim 10, wherein said heater is a ceramics heater prepared from ceramics mainly composed of aluminum nitride.

14. The semiconductor heater holder according to claim 10, wherein said semiconductor heater holder is made of metal.

15. The semiconductor heater holder according to claim 10, having a cooling unit.

16. The semiconductor heater holder according to claim 15, wherein a fluid is introduced into said cooling unit.

17. A semiconductor manufacturing apparatus comprising the semiconductor heater holder according to claim 10.

18. A semiconductor heater holder for setting a heater for heating a semiconductor, having an opening, a bottom portion opposed to said opening and a side portion extending from the periphery of said bottom portion toward said opening, wherein at least one of said bottom portion and said side portion is provided with a through-hole, and the area of said through-hole is not more than the area of a circle having a diameter corresponding to the height of said semiconductor heater holder.

19. The semiconductor heater holder according to claim 18, provided with a plurality of said through-holes to satisfy the relation A×B≧1 assuming that A (mm) represents the minimum distance between said through-holes and B (mm) represents the thickness of said semiconductor heater holder.

20. The semiconductor heater holder according to claim 18, comprising a support member forming a space between said semiconductor heater holder and a support when said semiconductor heater holder is set on said support.

21. The semiconductor heater holder according to claim 18, wherein said heater is a ceramics heater prepared from ceramics mainly composed of aluminum nitride, silicon nitride, silicon carbide, aluminum oxide or aluminum oxynitride.

22. The semiconductor heater holder according to claim 21, wherein said heater is a ceramics heater prepared from ceramics mainly composed of aluminum nitride.

23. The semiconductor heater holder according to claim 18, wherein said semiconductor heater holder is made of metal.

24. The semiconductor heater holder according to claim 18, having a cooling unit.

25. The semiconductor heater holder according to claim 24, wherein a fluid is introduced into said cooling unit.

26. A semiconductor manufacturing apparatus comprising the semiconductor heater holder according to claim 18.
